(19) United States
(12) Patent Application Publication
(10) Pub. No.: US 2022/0320003 A1
(43) Pub. Date: Oct. 6, 2022

(54) ALIGNMENT SCHEME OF MASK TO ZERO LAYER MARK UNDERNEATH EPI LAYER AND ON-CHIP IR GENERATION

(71) Applicant: SiEn (QingDao) Integrated Circuits Co., Ltd., Qingdao (CN)

(72) Inventor: Min-Hwa CHI, Qingdao (CN)

(73) Assignee: SiEn (QingDao) Integrated Circuits Co., Ltd., Qingdao (CN)

(21) Appl. No.: 17/707,707

(22) Filed: Mar. 29, 2022

(30) Foreign Application Priority Data
Apr. 6, 2021 (CN) 202110367798.3

(51) Int. Cl. H01L 23/544; H01L 21/266; H01L 21/68

(52) U.S. Cl. CPC H01L 23/544; H01L 21/266; H01L 21/682; H01L 2223/54426

(57) ABSTRACT

The present invention provides a mark of wafer alignment, a manufacturing method, a wafer alignment system and a method of aligning wafer. The mark of wafer alignment may generate self-emitting infrared light when applying a forward bias and conducted. When replacing infrared light incident externally with the self-emitting infrared light and using the mark of wafer alignment for alignment, because the infrared light is generated in the wafer directly, optical loss of the external infrared light in the light path from the epitaxy layer to the wafer may be omitted. The mark of wafer alignment may be broadly applied to semiconductor devices such as power MOS, IGBT, BCD and super junction device. Further, a structure of a wafer alignment system device aligning a wafer with such a mark of wafer alignment is simple without an additional He—Ne laser.

### FIELD OF THE INVENTION

The present invention relates to semiconductor photolithography technology, and especially relates to a mark of wafer alignment scheme, a manufacturing method, a wafer alignment device and a method of aligning wafer.

### BACKGROUND OF THE INVENTION

In semiconductor manufacturing, photolithography process is a key process for manufacturing integrated circuit (IC) chips. A chip may be made through dozens of photolithography process steps, and some structural layers may be formed through several photolithography process steps. The alignment between patterns (or alignment marks) on a mask and an existing pattern (or alignment marks) on a wafer is the most important step in a photolithography process. Alignment marks of each layer on wafers serve as a reference of position to perform the subsequent interlayer alignment to prevent from overlay errors among layers.

A certain number of grooves need to be formed on a wafer before performing a first process (e.g. epitaxy growth). As shown in FIGS. 1A and 1B, a substrate groove 111 on a substrate 11 are used as an initial alignment structure (referred to as zero layer mark). However, when growing an epitaxy layer 12 on the substrate 11, the epitaxy layer groove 121 formed on the substrate groove 111 is not totally copied from a pattern of the substrate groove 111 due to the epitaxy layer growth, instead, a shifted or distorted pattern or topology of the epitaxy layer groove 121 is formed as illustrated in FIGS. 1A and 1B respectively. Further, because the epitaxy layer 12 absorbs and reflects visible light 31, it is hard for ordinary visible light 31 passing through the epitaxy layer 12 and reaching a surface of the substrate 11. Therefore, with the use of visible light 31 for alignment, it is difficult to detect the reflection light from the substrate grooves 111 on the substrate 11, thus, the alignment with respect to the substrate groove 111 (or zero layer mark) is seriously deteriorated. As such, only the epitaxy layer groove 121 may be used as reference alignment mark; then the groove in epiaxial layer is not aligned well with respect to the groove 111 on Si substrate. Later, a technology referred to as “SMASH” (SMart Alignment Sensor Hybrid) was developed for alignment scheme in a ASML photolithography tool as illustrated in FIG. 2. The “SMASH” used infrared (IR) light to penetrate the epitaxy layer and diffraction of light, the periodically arranged grooves (i.e. gratings) in substrate serve as the reference alignment mark. After epitaxy layer is grown with proper thickness, a wafer 1 is then positioned on a wafer chuck 2. At this time, through the infrared light emitted by a He—Ne laser 3 illuminating the wafer 1 with the IR transparent to the epitaxy layer and reaching the Si substrate. With the help of diffraction of IR light by the substrate grooves, an interference pattern of light (i.e. alternating bright and dark stripes) will show. Then, a microscope 5 and an IR sensor 4 may be used to detect the pattern to perform accurate alignment through moving a chuck 2 on which the wafer is positioned that moves the substrate groove to a predetermined position as shown in FIGS. 3A and 3B. This method of the use of IR 32 penetrating through the epitaxy layer 12 and reaching a surface of the substrate 11 can prevent from the effect of the epitaxy layer 12 growth over the zero layer mark. Therefore, the substrate groove 111 is always used as a zero layer wafer alignment mark with no effect of patterns shift and distortion of the alignment mark in the epitaxy layer.

However, a He—Ne laser devoted to aforesaid “SMASH” is essential, and most current photolithography apparatuses lack the He—Ne laser and optical system adapted to the He—Ne laser. As it is costly for mounting a He—Ne laser and maintaining compatibility, thus a new structure of wafer alignment mark is needed to solve the above alignment problems.

### SUMMARY OF THE INVENTION

In light of aforesaid problems in the current technologies, an object of the present invention is to provide a structure of wafer alignment mark, a manufacturing method, a wafer alignment system and a method of aligning wafer to solve alignment problems in the current technologies.

An aspect of the present invention provides a structure of on-chip wafer alignment mark, comprising an infrared (IR) light emitter, the IR light emitter comprising: a substrate; a partial buried layer, formed on the substrate; and an epitaxy layer, formed on the substrate and on the partial buried layer; wherein a pn junction is formed between the substrate, the partial buried layer and the epitaxy layer as the IR light emitter, and the IR light emitter can be self-emitting IR light for alignment when forward biased.

Optionally, a conductivity type of the substrate may be p-type or n-type, and a conductivity type of the partial buried layer and/or a conductivity type of the epitaxy layer may be opposite to the conductivity type of the substrate.

Optionally, the structure of wafer alignment mark may comprise a substrate groove which generates diffraction patterns when illuminated by the infrared light.

Another aspect of the present invention provides a manufacturing method of a structure of wafer alignment mark, comprising steps of: step S1: providing a substrate, on a surface of which a photoresist layer is coated; step S2: patterning the photoresist layer through a photolithography process; step S3: ion implanting an area in which the photoresist layer is removed to form a partial buried layer; step S4: removing residual of the photoresist layer; and step S5: depositing an epitaxy layer on the substrate and on the partial buried layer; wherein at least one pn junction is formed between the substrate, the partial buried layer and the epitaxy layer to construct an infrared light emitter, and the infrared light emitter can be self-emitting infrared light emitter for alignment when forwarded biased.

Optionally, a conductivity type of the substrate may be p-type or n-type, and a conductivity type of the partial buried layer and/or the epitaxy layer may be opposite to the conductivity type of the substrate.

Optionally, the manufacturing method of a structure of wafer alignment mark may comprise: before the step S5, forming a substrate groove on the substrate through an etching process, and the substrate groove generating diffraction patterns when illuminated by the infrared light.

Yet, another aspect of the present invention provides a wafer alignment system, comprising a conductive chuck positioning a wafer, a microscope, an infrared sensor and an ionizer are positioned on the conductive chuck, and a mark of wafer alignment scheme carried by the wafer comprising: a substrate; a partial buried layer, formed on the substrate; and an epitaxy layer, formed on the wafer and on the partial buried layer; wherein a pn junction is formed between the substrate, the partial buried layer and the epitaxy layer as an infrared light emitter, and the infrared light emitter can be self-emitting infrared light for alignment when forward biased.

Optionally, additional light source therein comprises a broad band light source or a visible light source, the light source is pulsed light source, and a duty cycle of the pulse light source is within 30%-70%.

Another aspect of the present invention provides a method of aligning wafer, comprising steps of: step D1: providing a wafer carrying a mark of wafer alignment scheme comprising: a substrate; a partial buried layer, formed on the substrate; and an epitaxy layer, formed on the wafer and on the partial buried layer; wherein a pn junction is formed between the substrate, the partial buried layer and the epitaxy layer as an infrared light emitter, and the infrared light emitter can be self-emitting infrared light for alignment when forward biased; step D2: charging the mark of wafer alignment to make the infrared light emitter forward-biased and conducted; and step D3: using the difraction patterns as generated from the substrate grooves when illuminated by infrared light from the infrared light emitter or other infrared light as a reference of wafer position, then moving the wafer to a predetermined position to maximize the alignment signal to complete alignment.

Optionally, in the step D3, a light source is used to illuminate a surface of the wafer to increase a signal-to-noise ratio of the reference, the light source comprises a broad-band light source or a visible light source, the light source is pulse light source, and a duty cycle of the pulse light source is within 30%-70%.

As mentioned above, the structure of wafer alignment mark, manufacturing method, wafer alignment device and method of aligning wafer of the present invention may bring benefits as follows. The mark of wafer alignment scheme may generate self-emitting infrared light when applying a forward bias and conducted. When replacing infrared light incident externally with the self-emitting infrared light and using the mark of wafer alignment scheme for alignment, because the infrared light is generated in the wafer directly, optical loss of the external infrared light in the light path from the epitaxy layer to the wafer may be omitted. The mark of wafer alignment scheme may be broadly applied to semiconductor devices such as power MOS, IGBT, BCD and super junction device. Further, a structure of a wafer alignment device aligning a wafer with such a mark of wafer alignment scheme is simple without an additional He—Ne laser. The device may use a light source to increase a signal-to-noise ratio of the infrared light, and may be implemented in a current photolithography apparatus.

### BRIEF DESCRIPTION OF THE DRAWINGS

Various objects and advantages of the present invention will be more readily understood from the following detailed description when read in conjunction with the appended drawing as follows.

FIGS. 1A and 1B show perspective views when aligning with a visible light in a current technology.

FIG. 2 shows a perspective view of an apparatus used in “SMASH” technology.

FIGS. 3A and 3B show perspective views when aligning with an incident external infrared light in “SMASH” technology.

FIG. 4 shows a perspective view of an infrared light emitter of a structure of wafer alignment mark according to an embodiment of the present invention.

FIGS. 5A-5C show perspective views of a structure of wafer alignment mark with a substrate groove according to an embodiment of the present invention.

FIG. 6 shows a perspective view of a wafer alignment system according to an embodiment of the present invention.

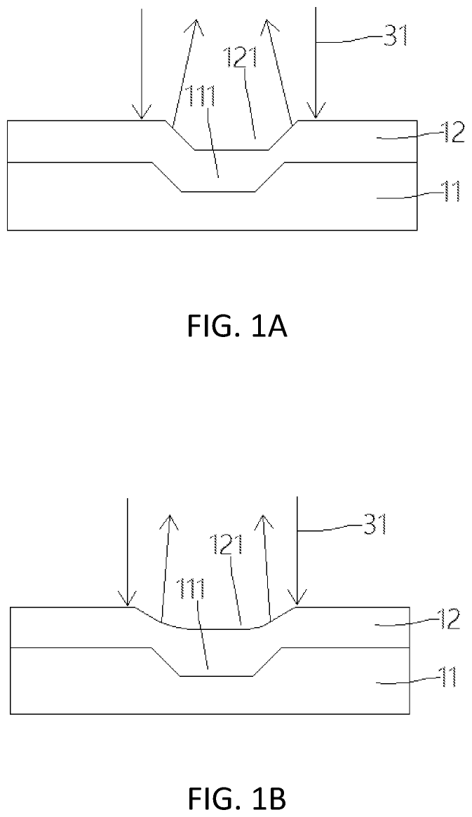

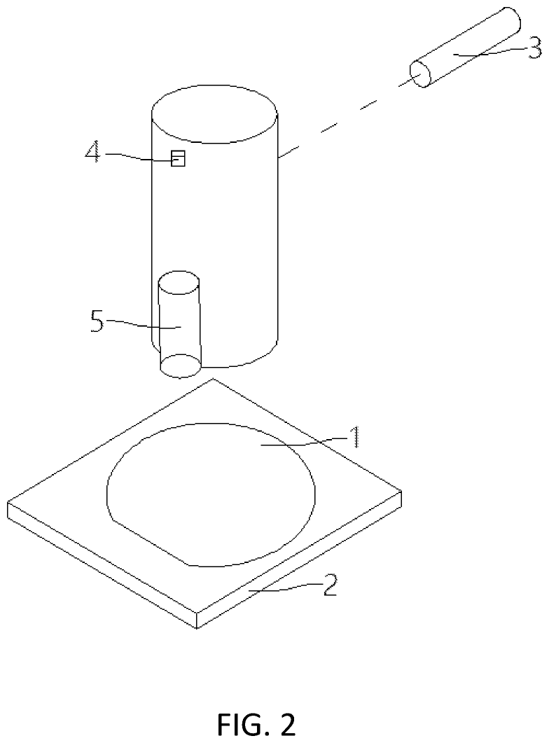

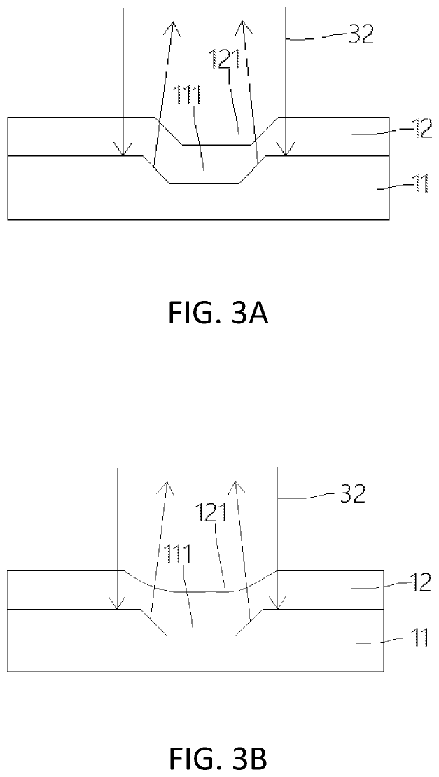

### DESCRIPTION OF EMBODIMENTS OF THE INVENTION

Reference is now made to the following concrete examples taken in conjunction with the accompanying drawings to illustrate implementation of the present invention. Persons of ordinary skill in the art having the benefit of the present disclosure will understand other advantages and effects of the present invention. The present invention may be implemented with other examples. For various view or application, details in the present disclosure may be used for variation or change for implementing embodiments within the scope of the present invention.

Please note that the drawings provided here are only for examples but not limited to the specific number or scale shown therein. When implementing the examples according to the drawings, condition, number and proportion of each element may be changed and arrangement of the elements may be in a more complex way in three-dimensional sizes such as length, width and depth. Cross-sectional views may be enlarged but not in proportion.

Please also note that terms to illustrate spatial relation used here, such as “below,” “under,” “lower than,” “on,” “above,” etc., are taken to describe a relation between an element or feature and other element(s) or feature(s). It is readily to be understood that such terms comprise other direction(s) of an operating device not shown in the figures. Further, when a layer is described as being between two layers, it may be the only layer or layered having other layer(s) between the two layers. “Between” comprises values at two ends.

Please further note that when describing a first feature is on a second feature, such description comprises an embodiment in which the first feature is in direct contact with the second feature and another embodiment in which the first feature is in indirect contact with the second feature and another feature is formed therebetween.

Please note that the drawings provided here are only for examples but not limited to the specific number or scale shown therein. When implementing the examples according to the drawings, condition, number, shape, size, relative position and proportion of each element may be changed and arrangement of the elements may be in a more complex way.

### First Embodiment

The present embodiment provides a structure of wafer alignment mark which comprises an infrared light emitter used for generating infrared light on-chip.

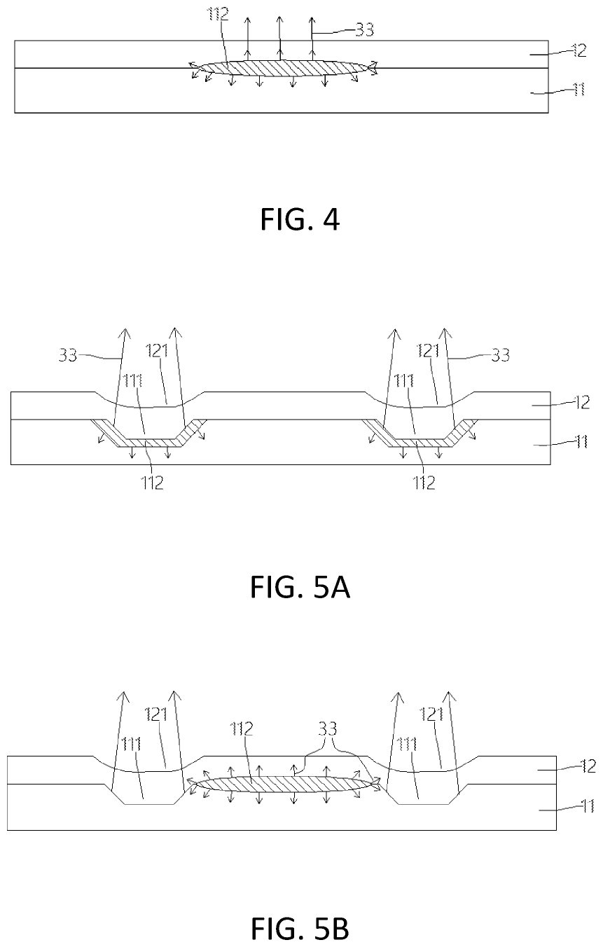

As show in FIG. 4, the infrared light emitter may specifically comprise: a substrate 11; a partial buried layer 112, formed on the substrate 11; an epitaxy layer 12, formed on the substrate 11 and on the partial buried layer 112; wherein at least one pn junction is formed between the substrate 11, the partial buried layer 112 and the epitaxy layer 12 as the infrared light emitter, and the infrared light emitter can be self-emitting infrared light emitter for alignment when forward biased.

In the exemplary embodiment, a conductivity type of the substrate 11 may be p-type or n-type, a conductivity type of the partial buried layer 112 and/or a conductivity type of the epitaxy layer 12 may be opposite to the conductivity type of the substrate 11.

Specifically, as shown in Table 1, the conductivity type of the substrate 11, the conductivity type of the partial buried layer 112 and the conductivity type of the epitaxy layer 12 may form at least six combinations.

TABLE 1

| The epitaxy | n-type | p-type | n-type | p-type | p-type | n-type |
|---|---|---|---|---|---|---|
| layer 12 | | | | | | |
| The partial | p-type | n-type | n-type | p-type | n-type | p-type |
| buried layer | | | | | | |
| 112 | | | | | | |
| The substrate | p-type | p-type | p-type | n-type | n-type | n-type |
| 11 | | | | | | |

When the pn junction formed by the substrate 11, the partial buried layer 112 and the epitaxy layer 12 is charged in forward bias manner and conducted, electrons and holes are injected and may be radiatively recombined, and emission spectrum may be divided into three regions: a first region, underneath a bandgap energy associated with radiative transition of the holes; a second region, a near edge region associated with radiative recombination of electrons and holes; a third region, i.e. a high-energy region, for example a wavelength range of visible light generated due to transition of hot electrons in a conduction band. Photon energy corresponding to the emission spectrum in the second region is 1.1 eV, which is in infrared light band. Therefore, when the infrared light emitter is charged in forward bias manner and conducting, the pn junction formed between the substrate 11, the partial buried layer 112 and the epitaxy layer 12 may generate self-emitting infrared light 33. The self-emitting infrared light 33 may pass through the epitaxy layer 12 rather than being reflected or absorbed, and may be freely scattered in the epitaxy layer 12. As such, the self-emitting infrared light 33 may be used as a light source, so as to do alignment through the self-emitting infrared light 33 generated by the infrared light emitter without the need of an additional He—Ne laser.

The present embodiment further provides a manufacturing method of a structure of wafer alignment mark, comprising steps of: step S1: providing a substrate, on a surface of which a photoresist layer is coating; step S2: patterning the photoresist layer through a photolithography process; step S3: ion implanting an area in which the photoresist layer is removed to form a partial buried layer; step S4: removing residual of the photoresist layer; and step S5: depositing an epitaxy layer on the substrate and on the partial buried layer; wherein at least one pn junction is formed between the substrate, the partial buried layer and the epitaxy layer as an infrared light emitter, and the infrared light emitter can be self-emitting infrared light for alignment when forward biased.

Specifically, a conductivity type of the substrate 11 may be p-type or n-type, and a conductivity type of the partial buried layer 112 and/or the epitaxy layer 12 may be opposite to the conductivity type of the substrate 11. As such, at least one pn junction may be formed between the substrate 11, the partial buried layer 112 and the epitaxy layer 12 to construct the infrared light emitter, and perform alignment with the self-emitting infrared light 33 generated through the forward biased infrared light emitter. As shown in Table 1, the conductivity type of the substrate 11, the conductivity type of the partial buried layer 112 and the conductivity type of the epitaxy layer 12 may form at least six combinations.

When the structure of wafer alignment mark made with the manufacturing method is charged in forward bias manner and conducting, the pn junction formed between the substrate 11, the partial buried layer 112 and the epitaxy layer 12 may generate the self-emitting infrared light 33 when forward biased. The self-emitting infrared light 33 may pass through the epitaxy layer 12 rather than being reflected or absorbed, and may be freely scattered in the epitaxy layer 12. As such, the self-emitting infrared light 33 may be used as a IR light source, so as to perform alignment through the self-emitting infrared light 33 generated by the infrared light emitter without the need of an additional He—Ne laser.

### Second Embodiment

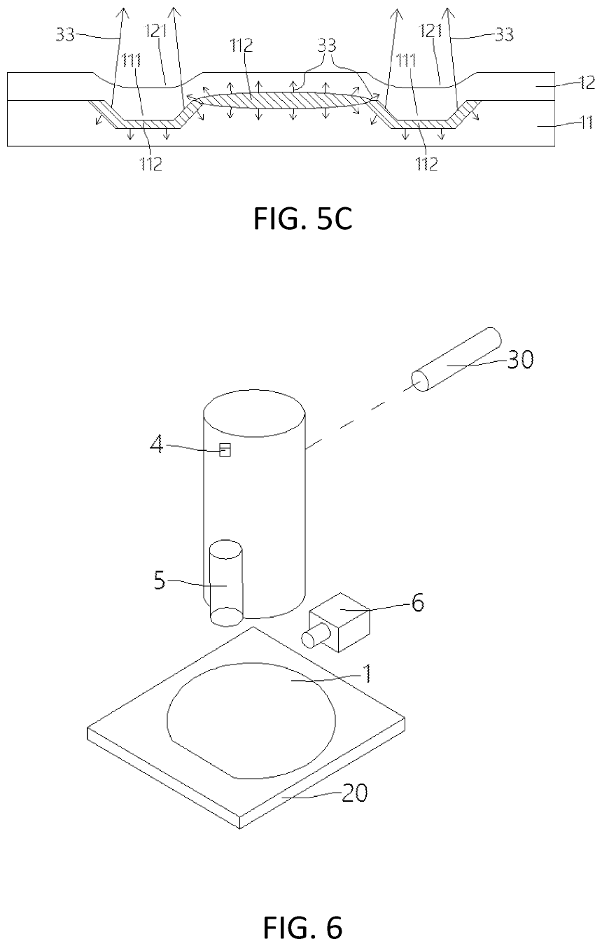

Based on the infrared light emitter of the first embodiment, in the present embodiment, a substrate groove is positioned on the wafer as shown in FIGS. 5A-5C. The mark of wafer alignment may further comprise: a substrate groove 111, the substrate groove 111 being positioned on the substrate 11, and diffraction patterns are generated when the substrate groove 111 is illuminated by the self-emitting infrared light 33.

In the exemplary embodiment, the substrate groove 111 may be positioned in an intrinsic region and/or a peripheral region of the infrared light emitter, and may comprise three arrangements shown in FIGS. 5A to 5C: as shown in FIG. 5A, the substrate groove 111 is positioned in the intrinsic region of the infrared light emitter, i.e. the infrared light emitter comprises the substrate groove 111; as shown in FIG. 5B, the substrate groove 111 is positioned in the periphery region of the infrared light emitter, i.e. the substrate groove 111 is formed at periphery of the infrared light emitter; as shown in FIG. 5C, the substrate groove 111 is positioned in the intrinsic region and the peripheral region of the infrared light emitter.

Specifically, the substrate groove 111 may be used to generate the diffraction patterns. When the infrared light emitter is charged in forward bias manner to emit the self-emitting infrared light 33, the substrate groove 111, illuminated by the self-emitting infrared light 33, may generate the diffraction patterns. Therefore, the diffraction patterns may be used as signals, which is more accurate compared with the self-emitting infrared light 33 of the first embodiment.

When the substrate groove 111 is positioned at the periphery region of the infrared light emitter, i.e. the arrangement shown in FIG. 5B, photons of the self-emitting infrared light 33 may travel in substrate and reflect at an interface, so as to illuminate the substrate groove 111 to generate the diffraction patterns.

When the substrate groove 111 is positioned in the intrinsic region and the peripheral region of the infrared light emitter in forward bias manner, i.e. the arrangement shown in FIG. 5C, the self-emitting infrared light 33 may be emitted from the substrate groove 111 directly to illuminate the substrate groove 111 to generate the diffraction patterns. As such, such an arrangement has structural features of both FIG. 5A and FIG. 5B, for better IR illumination.

In the present embodiment, a manufacturing method of a structure of wafer alignment mark in the substrate groove 111 may be added with a step of forming the substrate groove 111 based on the manufacturing method disclosed in the first embodiment, and may be specified as: before the step S5, forming the substrate groove 111 on the substrate 11 through an etching process, and the substrate groove 11 generating diffraction patterns when illuminated by the self-emitting infrared light 33.

In the present embodiment, the substrate groove 111 may be positioned in an intrinsic region and/or a peripheral region of the infrared light emitter, and may comprise three arrangements shown in FIGS. 5A to 5C: as shown in FIG. 5A, the substrate groove 111 is positioned in the intrinsic region of the infrared light emitter, i.e. the infrared light emitter comprises the substrate groove 111; as shown in FIG. 5B, the substrate groove 111 is positioned in the periphery region of the infrared light emitter, i.e. the substrate groove 111 is formed at periphery of the infrared light emitter; as shown in FIG. 5C, the substrate groove 111 is positioned in the intrinsic region and the peripheral region of the infrared light emitter.

### Third Embodiment

The present embodiment provides a wafer alignment system which may be used along with the mark of wafer alignment scheme of the first and second embodiments to do alignment. The wafer alignment system may comprise a conductive chuck 20 for positioning a wafer 1, the conductive chuck 20 being conductive; a microscope 5 and an infrared sensor 4 on the conductive chuck 20, the microscope 5 and the infrared sensor 4 for observing self-emitting infrared light emitted from the wafer 1; an ionizer 6 positioned on the conductive chuck 20; and a further light source 30, the ionizer 6 for negative ions injection to carry out electrical conduction of a pn junction (in forward bias manner) in the infrared light emitter through the ionizer 6 and the conductive chuck 20, so as to generate the self-emitting infrared light. As such, the self-emitting infrared light may be captured through the microscope 5 and the infrared sensor 4 for alignment. The light source 30 may be used for illumination to increase a signal-to-noise ratio (S/N ratio) of the infrared light. The light source 30 may comprise a broad band light source or a visible light source.

The wafer alignment system may be used in this way: the wafer 1 with the mark of wafer alignment in substrate may be put on the conductive chuck 20, a lower surface of the wafer 1 may contact with the conductive chuck 20, and then the conductive chuck 20 may be charged. Meanwhile, the ionizer 6 may be used to inject charged ions toward an upper surface of the wafer 1. A cathode and anode of the conductive chuck 20 and positive and negative polarity of the charged ions injected by the ionizer 6 depend on a conductivity type of the mark of wafer alignment scheme of the wafer 1. The infrared light emitter of the mark of wafer alignment scheme may be forward biased and conducting, so as to generate the self-emitting infrared light 33. Later, through the microscope 5 and the infrared sensor 4, the self-emitting infrared light 33 or refraction stripes generated through the self-emitting infrared light 33 illuminating the substrate groove 111 may be detected. The alignment may be done with the refraction stripes as reference and through moving the conductive chuck 20 to move the reference to a predetermined position.

Further, when doing alignment, a light source 30 may be optionally used to illuminate a surface of the wafer 1 to increase a signal-to-noise ratio of the infrared light. In the present embodiment, the light source 30 may be a pulsed light source, a duty cycle of the pulse light source may be within 30%-70% to obtain a higher duty cycle, and preferably the duty cycle may be 50%.

### Fourth Embodiment

The present embodiment provides a method of aligning wafer, comprising steps of: step D1: providing a wafer carrying a mark of wafer alignment scheme of the first or second embodiment; step D2: charging the mark of wafer alignment to make the infrared light emitter forward-biased and conducting; and step D3: using diffraction patterns generated when illuminating the substrate groove with the self-emitting infrared light from the forward biased infrared light emitter or other self-emitting infrared light as a reference of wafer position, then moving the wafer to a predetermined position to maximize the alignment signal to complete the alignment.

In the present embodiment, in the step D3, a light source may be used to illuminate a surface of the wafer to increase a signal-to-noise ratio of the reference, the light source may comprise a broad-band light source or a visible light source, the light source may be pulsed light source, and a duty cycle of the pulse light source may be within 30%-70% to obtain a higher signal-to-noise ratio, and preferably, the duty cycle may be 50%.

As mentioned above, the structure of wafer alignment may generate self-emitting infrared light when applying a forward bias and conducting. When replacing infrared light incident externally with the self-emitting infrared light and using the mark of wafer alignment for alignment, because the infrared light is generated in the wafer directly, optical loss of the external infrared light in the light path from the epitaxy layer to the wafer may be omitted. The mark of wafer alignment may be broadly applied to semiconductor devices such as power MOS, IGBT, BCD and super junction device. Further, a structure of a wafer alignment system aligning a wafer with such a mark of wafer alignment is simple without an additional He—Ne laser. The device may use a light source to increase a signal-to-noise ratio of the infrared light, and may be implemented in a current photolithography apparatus.

It is to be understood that these embodiments are not meant as limitations of the invention but merely exemplary descriptions of the invention. Indeed, different adaptations may be apparent to those skilled in the art without departing from the scope of the annexed claims.

What is claimed is:

1. A structure of wafer alignment mark, comprising an infrared light emitter, the infrared light emitter comprising:
a substrate;
a partial buried layer, formed on the substrate; and
an epitaxy layer, formed on the substrate and on the partial buried layer;
wherein a pn junction is formed between the substrate, the partial buried layer and the epitaxy layer to construct the infrared light emitter, and self-emitting infrared light occurs through the forward biased infrared light emitter for alignment.

2. The structure of wafer alignment mark according to claim 1, wherein a conductivity type of the substrate is p-type or n-type, and a conductivity type of the partial buried layer and/or a conductivity type of the epitaxy layer is opposite to the conductivity type of the substrate.

3. The structure of wafer alignment mark according to claim 1, further comprising a substrate groove which generates diffraction patterns when illuminated by the self-emitting infrared light.

4. A manufacturing method of a structure of wafer alignment mark, comprising steps of:
step S1: providing a substrate, on a surface of which a photoresist layer is coating;
step S2: patterning the photoresist layer through a photolithography process;
step S3: ion implanting an area in which the photoresist layer is removed to form a partial buried layer;
step S4: removing residual of the photoresist layer; and
step S5: depositing an epitaxy layer on the substrate and on the partial buried layer;
wherein at least one pn junction is formed between the substrate, the partial buried layer and the epitaxy layer to construct an infrared light emitter, and the infrared light emitter can be self-emitting infrared light for alignment when forward biased.

5. The manufacturing method of a structure of wafer alignment mark according to claim 4, wherein a conductivity type of the substrate is p-type or n-type, and a conductivity type of the partial buried layer and/or the epitaxy layer is opposite to the conductivity type of the substrate.

6. The manufacturing method of a structure of wafer alignment mark according to claim 4, further comprising:
before the step S5, forming a substrate groove on the substrate through an etching process, and the substrate groove generating diffraction patterns when illuminated by the self-emitting infrared light.

7. A wafer alignment system, comprising a conductive chuck positioning a wafer, a microscope, an infrared sensor and an ionizer are positioned on the conductive chuck, and a structure of wafer alignment mark carried by the wafer according to claim 1 comprising:
a substrate;
a partial buried layer, formed on the substrate; and
an epitaxy layer, formed on the wafer and on the partial buried layer;
wherein a pn junction is formed between the substrate, the partial buried layer and the epitaxy layer to construct an infrared light emitter, and the infrared light emitter can be self-emitting infrared light for alignment.

8. The wafer alignment system according to claim 7, wherein a light source therein comprises a broad band light source or a visible light source, the light source is pulsed light source, and a duty cycle of the pulse light source is within 30%-70%.

9. A method of aligning wafer, comprising steps of:
step D1: providing a wafer with a structure of wafer alignment mark comprising:
a substrate;
a partial buried layer, formed on the substrate; and
an epitaxy layer, formed on the wafer and on the partial buried layer;
wherein a pn junction is formed between the substrate, the partial buried layer and the epitaxy layer to construct an infrared light emitter, and the infrared light emitter can be self-emitting infrared light for alignment;
step D2: charging the mark of wafer alignment scheme to make the infrared light emitter forward-biased and conducted; and
step D3: using the diffraction patterns as generated from the substrate grooves when illuminated by the infrared light from the self-emitting infrared light emitter or other self-emitting infrared light as a reference of wafer, then moving the wafer to a predetermined position for achieving a maximum alignment signal of the mask in order to complete the alignment.

10. The method of aligning wafer according to claim 9, wherein in the step D3, an optional light source is used to illuminate a surface of the wafer to increase a signal-to-noise ratio of the reference, the light source comprises a broad-band light source or a visible light source, the light source is pulsed light source, and a duty cycle of the pulse light source is within 30%-70%.
